(19) United States
(12) Patent Application Publication
(10) Pub. No.: US 2008/0094053 A1
(43) Pub. Date: Apr. 24, 2008

(54) Test circuits having ring oscillators and test methods thereof

(75) Inventors: Yong-Woon Han, Suwon-si (KR); Ki-Am Lee, Anyang-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/889,418

(22) Filed: Aug. 13, 2007

(30) Foreign Application Priority Data
Oct. 24, 2006 (KR) 10-2006-0103293

(51) Int. Cl. G01R 23/02

(52) U.S. Cl. 324/76.39

(57) ABSTRACT

In a test circuit, an oscillation signal is generated based on a design rule pattern of a chip formed on a wafer. The oscillation signal is counted using a counter, and an N-bit signal is generated from the counting of the oscillation signal. The N-bit signal is serialized and output. In a test method, an oscillation signal is generated based on a design rule pattern of a chip formed on a wafer. The oscillation signal is counted, and an N-bit signal is generated based on the counting of the oscillation signal. The N-bit signal is serialized and output.

### PRIORITY STATEMENT

This non-provisional patent application claims priority under 35 U.S.C. § 119 to Korean Patent Application No. 10-2006-0103293, filed on Oct. 24, 2006, in the Korean Intellectual Property Office (KIPO), the entire contents of which is hereby incorporated herein by reference.

### BACKGROUND

### Description of the Related Art

Conventional semiconductor manufacturing processes include four sub-processes from a first wafer manufacturing process to a completed process. For example, a conventional semiconductor manufacturing process may include a wafer manufacturing process in which a wafer is manufactured from silicon raw ore, a wafer processing process in which an integrated circuit is formed on the manufactured wafer, a package assembling process in which a chip is manufactured using the processed wafer, and a module assembling process in which the package is mounted onto a module to obtain a finished product.

In the package assembling process, the operating frequency and the current-to-voltage characteristics of the chip designed on the wafer are tested. The chip is categorized and cut according to the test result, and the cut chip is packaged. The package assembling process allows an initial “FAILURE” in each chip to be sensed to sort out normal chips, and diagnose the cause of the “FAILURE” to increase production efficiency and reduce manufacturing costs.

FIG. 1 is a diagram illustrating a chip C1 formed on a conventional wafer 5. Referring to FIG. 1, in a conventional package assembling process, the wafer 5 is cut according to a plurality of scribe lines S1 through S5, and the resultant chip C1 is packaged. Before cutting the wafer 5, a test circuit including a ring oscillator may be used to test the chip C1 operating on the wafer 5 at relatively high speeds. The test circuit is disposed in a scribe line region T1.

In one example, the ring oscillator included in the test circuit generates an oscillation signal when the test circuit is connected to a pattern having a design rule of the chip C1, for example, a contact, an active resistor, a metal line or a poly resistor.

A conventional ring oscillator may be embodied as a delay chain composed of a plurality of inverters in which two adjacent inverters are connected in series via the pattern. In other words, for example, the pattern is connected between the output terminal of one of the two adjacent inverters and the input terminal of the other inverter. The output terminal and the input terminal act as probes. Accordingly, the ring oscillator generates the oscillation signal.

Conventionally, whether the chip C1 has a “FAILURE” is determined by measuring or calculating an oscillation frequency based on an oscillation signal generated for each pattern, and determining whether the oscillation frequency is less than or equal to a given reference frequency. However, when the size of the chip C1 is reduced and the operating frequency becomes relatively high, the oscillation frequency may increase in units of GHz, and measuring the oscillation frequency may be more difficult and require more expensive measuring equipment.

Also, an increase in a total number of pads included in the measuring equipment to measure an oscillation frequency may result in an increase in a ratio of the size of the scribe line region T1 to the size of the wafer 5. This may reduce the yield of the wafer 5.

### SUMMARY

Example embodiments relate to test circuits, for example, test circuits and methods for detecting a fault or “FAILURE” in a semiconductor device by using at least one ring oscillator.

Example embodiments provide test circuits and methods for measuring an oscillating frequency based on the pattern of a semiconductor device.

Example embodiments also provide test circuits and methods in which a total number of pads included in the test circuit may be reduced to allow the test circuit to be disposed on a scribe line of a wafer.

At least one example embodiment provides a test circuit including an oscillation unit generating an oscillation signal based on a design pattern of a chip formed on a wafer. The test circuit may further include an output unit configured to count the oscillation signal, serialize an N-bit signal generated from the counting of the oscillation signal, and output the serialized signal. N may be a natural number.

According to at least some example embodiments, the oscillation unit may include an oscillator unit having one or more ring oscillators, and a selecting unit configured to generate a selection signal for selecting a ring oscillator from among the one or more ring oscillators based on input signals. The oscillation signal may be output from the ring oscillator selected from among the one or more ring oscillators by the selection signal.

According to at least some example embodiments, the selecting unit may include a shift register configured to sequentially latch the input signals received via an input terminal in response to a clock signal, and generate at least one output signal. The selecting unit may further include a selection signal generating unit configured to generate the selection signal based on the at least one output signal. The output unit may include a counter configured to count the oscillation signal, and a serializer configured to serialize and output the N-bit signal generated by the counter. The serializer may be a shift register. The design rule pattern may be one of a contact, an active resistor, a metal line, a poly resistor or the like.

According to at least some example embodiments, the oscillation circuit may include a selecting circuit and an oscillator circuit. The oscillator circuit may include a plurality of ring oscillators. The selecting circuit may be configured to generate the selection signal based on an input signal, and the oscillator circuit may be configured to generate an oscillation signal in response to the selection signal.

At least one other example embodiment provides a test method for a semiconductor device. According to at least this example embodiment, the test method may include generating an oscillation signal based on a design rule pattern of a chip formed on a wafer, counting the oscillation signal, serializing an N-bit signal generated from the counting of the oscillation signal, and outputting the serialized signal. N may be a natural number.

According to at least some example embodiments, the test method may further include calculating an oscillation frequency of the oscillator based on the serialized signal, comparing the calculated oscillation frequency with a reference frequency of the design rule pattern, and determining whether the chip formed on the wafer is acceptable based on the comparing result. The generating of the oscillation signal may include generating a selection signal for selecting a ring oscillator from among one or more ring oscillators included in an oscillation unit based on input signals. According to at least one example embodiment, whether the chip is “GOOD” or is a “FAILURE” may be determined.

According to at least some example embodiments, the generating of the selection signal may include sequentially latching the input signals received via an input terminal in response to a clock signal, outputting at least one output signal, and generating the selection signal based on the at least one output signal. The outputting of the serialized signal may include counting the oscillation signal, serializing and outputting the N-bit signal generated from the counting of the oscillation signal. The outputting of the serialized signal may be performed by a shift register. The design rule pattern may be one of a contact, an active resistor, a metal line, a poly resistor or the like.

### BRIEF DESCRIPTION OF THE DRAWINGS

The present invention will become more apparent by describing in detail example embodiments thereof with reference to the attached drawings in which:

FIG. 1 illustrates a conventional chip disposed on a wafer;

FIG. 2 is a functional block diagram of a test circuit according to an example embodiment;

FIG. 3 is a circuit diagram illustrating the test circuit of FIG. 2 in detail;

FIGS. 4A and 4B are respectively a circuit diagram and a circuit pattern of a ring oscillator, of the test circuit of FIG. 2, which is connected to a pattern;

FIG. 5 is a timing diagram illustrating the operation of the test circuit of FIG. 2; and

FIG. 6 is a flowchart illustrating a test method according to an example embodiment.

### DETAILED DESCRIPTION OF EXAMPLE EMBODIMENTS

Various example embodiments of the present invention will now be described more fully with reference to the accompanying drawings in which some example embodiments of the invention are shown. In the drawings, the thicknesses of layers and regions are exaggerated for clarity.

Detailed illustrative embodiments of the present invention are disclosed herein. However, specific structural and functional details disclosed herein are merely representative for purposes of describing example embodiments of the present invention. This invention may, however, may be embodied in many alternate forms and should not be construed as limited to only the embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

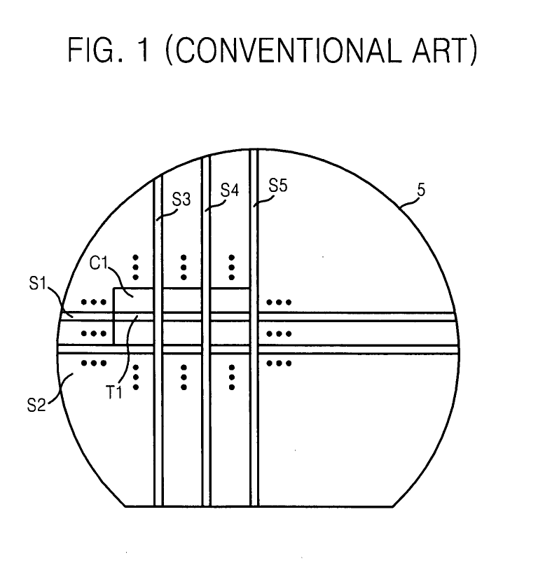

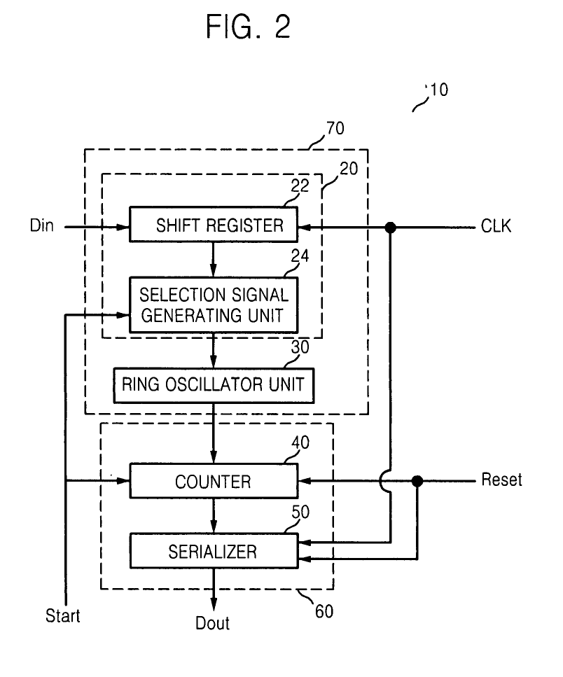

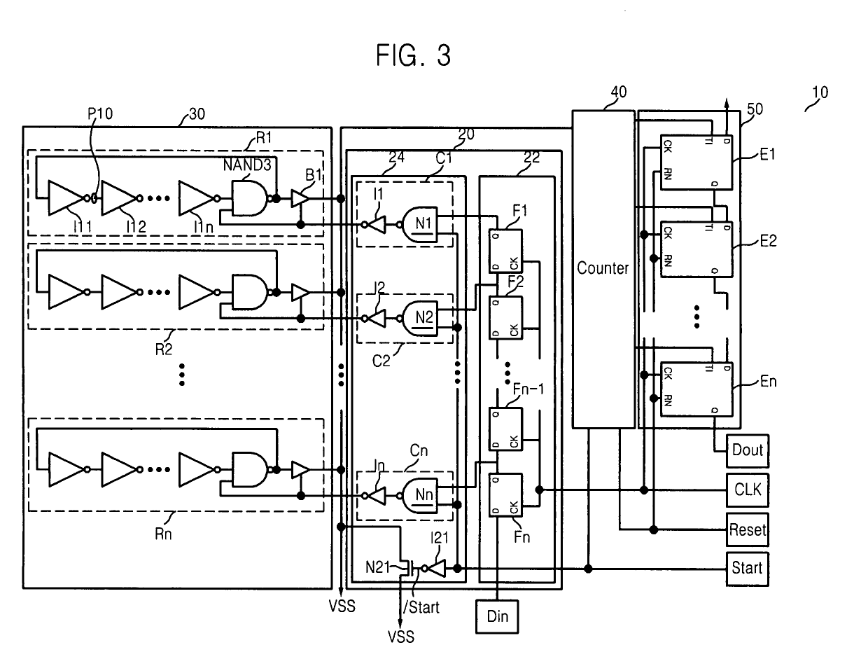

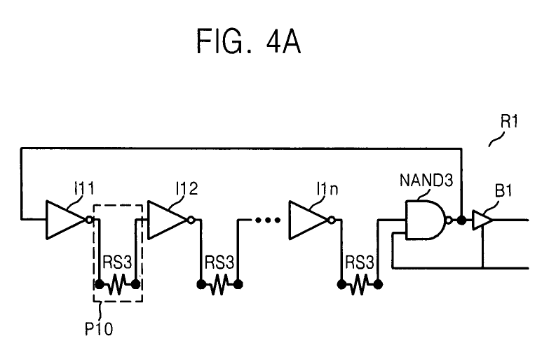

FIG. 2 is a functional block diagram of a test circuit according to an example embodiment. FIG. 3 is a circuit diagram illustrating the example test circuit of FIG. 2. FIG. 4A is a circuit diagram of a ring oscillator of a test circuit according to an example embodiment. FIG. 4B is a circuit pattern of a ring oscillator according to an example embodiment. According to example embodiments, the ring oscillator of FIG. 4A or 4B may be included in the test circuit of FIG. 1.

Referring to FIGS. 2 through 4B, the test circuit 10 may include an oscillation circuit or unit 70 and an output circuit or unit 60. The oscillation unit 70 may generate an oscillation signal based on a design rule pattern of a chip formed on a wafer. The output unit 60 may count the oscillation signal, serialize an N-bit signal generated from the counting of the oscillation signal, and output the serialized signal. N may be any natural number.

The oscillation unit 70 may include a selecting circuit or unit 20 and an oscillator circuit or unit 30. For example purposes, each components of the test circuit 10 will be described as a unit (e.g., oscillation unit 70, output unit 60, etc.) However, it will be understood each of these components may be circuit, and may be referred to as such.

The selecting unit 20 may generate a selection signal for selecting a ring oscillator from among one or more ring oscillators R1 through Rn included in the oscillator unit 30. The selecting unit 20 may include a shift register 22 and a selection signal generating circuit or unit 24. The shift register 22 may include one or more flip-flops F1 through Fn, and may latch (e.g., sequentially latch) input signals received via an input terminal Din to generate at least one output signal, in response to a clock signal CLK.

The selection signal generating unit 24 may generate the selection signal for selecting a ring oscillator from among the one or more ring oscillators R1 through Rn based on the at least one output signal generated by the shift register 22. The selection signal generating unit 24 may include one or more logic gates N1 through Nn (e.g., one or more NAND gates) and one or more inverters I1 through In. The selection signal generating unit 24 will be discussed herein with regard to the example structure shown in FIG. 3. However, the selection signal generating unit 24 may be alternatively embodied as a plurality of logic gates such as AND gates.

Still referring to FIGS. 2 and 3, each of the one or more NAND gates N1 through Nn may receive a corresponding signal output from the shift register 22 and a first control signal Start. The NAND gates N1 through Nn may perform a NAND operation on the received signals, and output the operation result to a corresponding one of the inverters I1 through In.

Each of the inverters I1 through In may invert a signal output from a corresponding one of the NAND gates N1 through Nn, to output a selection signal to a corresponding ring oscillator in the oscillator unit 30. Each selection signal may enable a corresponding one of the ring oscillators R1 through Rn included in the oscillator unit 30.

The selection signal generating unit 24 may further include a switch SW, which may be turned on or off in response to an output signal /Start. The switch N21 may be a transistor (e.g., an MOS transistor such as an NMOS or PMOS transistor). To generate the output signal /Start, the first control signal Start may be inverted by inverter I21 connected between a gate of the switch N21 and an input terminal of the selection signal generating unit 24. According to example embodiments, if the switch N21 is embodied as an MOS transistor, the output signal/Start from the inverter I21 may be input to a gate of the MOS transistor.

Because electric charges remaining in the output terminal of the oscillator unit 30 may be relatively rapidly discharged by the switch N21, the response speed of the counter 40 may be increased.

As discussed above, the oscillator unit 30 may include one or more ring oscillators R1 through Rn. When a ring oscillator, for example, the ring oscillator R1 is enabled by the selection signal, the ring oscillator R1 connected to the design rule pattern may generate an oscillation signal.

For example, the ring oscillator R1 may include an even number of inverters I1 through I1n, a logic gate NAND3 (e.g., a NAND gate) and/or a buffer B1. Corresponding design rule patterns (not shown in FIG. 3) may be connected in respective spaces, for example, spaces P10, among the inverters I11 through I1n and the logic gate NAND3 via probe terminals to form an electric current path.

Thus, the ring oscillator R1 connected to the design rule pattern may generate the oscillation signal. The ring oscillator R1 may further include the buffer B1 for buffering the oscillation signal. Each buffer B1 may operate in response to a corresponding selection signal output from the selection signal generating unit 24.

When active resistors RS3 illustrated in FIG. 4A are respectively connected in spaces P10 between the inverters I11 through I1n and the NAND gate NAND3 via probe terminals of the ring oscillator R1, an electric current path may be formed, thus enabling the ring oscillator R1 to generate an oscillation signal. Similarly, when a metal line M3 illustrated in FIG. 4B is connected in the spaces P10 between the inverters I11 through I1n and the NAND gate NAND3 via probe terminals of the ring oscillator R1, an electric current path may be formed, thus enabling the ring oscillator R1 to generate the oscillation signal.

Referring back to FIGS. 2 and 3, the output unit 60 may include a counter 40 and a serializer 50. The counter 40 may count the oscillation signal generated by the ring oscillator R1. For example, the counter 40 may count a number of times the logic level of the oscillation signal transitions (e.g., from a high logic level to a low logic level or from a low logic level to a high logic level), and generate an N-bit signal corresponding to the counting result. The number N may be any natural number.

The serializer 50 may serialize the N-bit signal generated by the counter 40 to output a serialized signal via output terminal Dout. When the serializer 50 is embodied as a shift register including a plurality of registers E1 through En, the serializer 50 may be capable of serializing the N-bit signal received in parallel and outputting the serialized signal via the output terminal Dout based on a clock signal CLK.

According to at least some example embodiments, even if the frequency of the oscillation signal based on a design rule pattern is increased, the ring oscillator R1 may be capable of counting (e.g., relatively precisely counting) the oscillation signal using the counter 40. Thus, additional, more expensive equipment may not be required. Additionally, because signals may be serialized and output via one output terminal Dout, the size of test circuit 10 may be reduced.

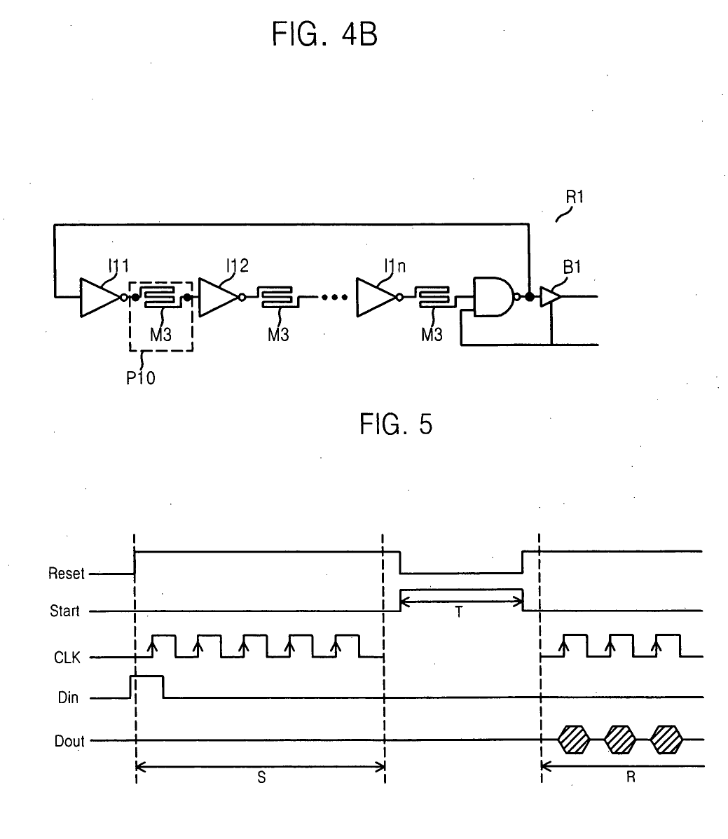

FIG. 5 is a timing diagram illustrating the operation of the test circuit 10 of FIG. 2. Referring to FIGS. 2 through 5, a tester or a test device (not shown) may input an input signal at a first rising edge of a clock signal CLK via the input terminal Din to select a ring oscillator (e.g., the ring oscillator R1) during a ring oscillator selecting period S.

If the input signal is input at the first rising edge of the clock signal CLK, the first flip-flop F1 of the shift register 22 may output a signal having first logic state (e.g., a high level or high logic level) through level shifting, and the selection signal generating unit 24 may output a selection signal to enable the ring oscillator R1. A signal Reset may enter the first logic state to initialize the counter 40. If the ring oscillator R1 is selected, a signal Start may transition to the first logic state during an oscillation signal counting period T, and thus, the ring oscillator R1 may output an oscillation signal.

During a serializing period R, counted N-bit data may be serialized based on the clock signal CLK, and output via the output terminal Dout.

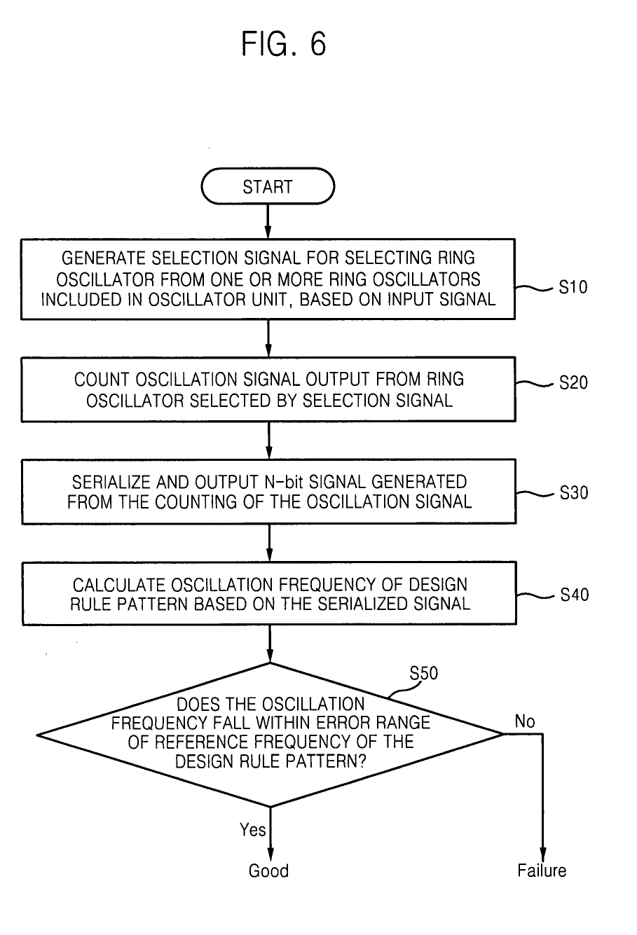

FIG. 6 is a flowchart illustrating a test method according to an example embodiment. For example purposes, the method of FIG. 6 will be discussed with regard to the test circuit of FIGS. 2 and 3 and the timing diagram of FIG. 5.

Referring to FIG. 6, at S10 the selecting unit 20 may generate a selection signal for selecting a ring oscillator from among the one or more ring oscillators R1 through Rn included in the oscillator unit 30 based on a received input signal.

At S20, the counter 40 may count an oscillation signal received from the selected ring oscillator (e.g., the ring oscillator R1). At S30, the serializer 50 may serialize an N-bit signal generated from the counting of the counter 40 and may output the serialized signal.

At S40, a tester or a test device (not shown) may calculate an oscillation frequency of a design rule pattern based on the serialized signal. The oscillation frequency may correspond to the result of dividing the counting result of the counter 40 by the duration or period of the oscillation signal counting time interval T (e.g., the period in which the signal Start is at a first logic state or high logic level),

At S50, the tester or the test device may determine whether the oscillation frequency falls within the error range of a reference frequency of the design rule pattern. The reference frequency may be a reference value allowing a chip formed on a wafer to operate normally. If the tester or test device determines that the oscillation frequency based on the design rule pattern falls within the error range of the reference frequency, the chip is determined to be acceptable or ‘GOOD’. Returning to S50, if the tester or test device determines that the oscillation frequency based on the design rule pattern does not fall within the error range of the reference frequency, the chip is determined to be unacceptable or a ‘FAILURE’.

According to at least some example embodiments, the selection signal may be generated based on an input signal received via the input terminal Din, and thus, a total number of pads included in the test circuit 10 may be less than in a conventional test circuit. Therefore, size of the test circuit may be reduced and/or minimized.

As described above, test circuits and test methods according to at least some example embodiments may be capable of more precisely measuring an oscillation frequency based on a design rule pattern of a chip formed on a wafer by using a counter. Also, in test circuits and test methods according to at least some example embodiments a total number of pads included in the test circuit may be reduced, thus allowing the test circuit to be disposed on a scribe line of a wafer, thereby increasing the yield of the wafer.

While the present invention has been particularly shown and described with reference to example embodiments thereof, it will be understood by those skilled in the art that various changes in form and details may be made therein without departing from the spirit and scope of the present invention as defined by the appended claims.

What is claimed is:

1. A test circuit comprising:
an oscillation circuit configured to generate an oscillation signal based on a design rule pattern of a chip formed on a wafer; and
an output circuit configured to count the oscillation signal, serialize an N-bit signal generated based on the counting of the oscillation signal, and output a serialized signal; wherein
N is a natural number.

2. The test circuit of claim 1, wherein the oscillation circuit includes,
a selecting circuit configured to generate a selection signal based on a input signal, and
an oscillator circuit configured to output the oscillation signal based on the selection signal.

3. The test circuit of claim 2, wherein the oscillator circuit includes at least one ring oscillator configured to output the oscillation signal in response to the selection signal output from the selecting circuit.

4. The test circuit of claim 3, wherein at least one of the at least one ring oscillators includes,
a logic circuit configured to generate an output signal based on the selection signal output from the selecting circuit and the output signal, the output signal being fed back to the logic circuit signal, and
a buffer configured to buffer the output signal.

5. The test circuit of claim 4, wherein the buffer buffers the output signal based on the selection signal.

6. The test circuit of claim 4, wherein the logic circuit includes,
a plurality inverters connected in series, each pair of consecutive inverters having a design rule pattern connected there between, and the plurality of serially connected inverters being configured to generate a first input signal based on the fed back output signal, and
a logic gate configured to generate the output signal by performing a logic operation on the first input signal and the selection signal output from the selecting circuit.

7. The test circuit of claim 1, wherein the design rule pattern is one of a contact, an active resistor, a metal line and a poly resistor.

8. The test circuit of claim 2, wherein the selecting circuit includes,
a shift register configured to sequentially latch the input signal received via an input terminal in response to a clock signal, and generate an output signal, and
a selection signal generating circuit configured to generate the selection signal based on the output signal.

9. The test circuit of claim 1, wherein the output circuit includes,
a counter configured to count the oscillation signal, and
a serializer configured to serialize and output the N-bit signal generated by the counter.

10. The test circuit of claim 9, wherein the serializer is a shift register.

11. The test circuit of claim 1, wherein the oscillation circuit includes,
a selecting circuit configured to generate a selection signal based on an input signal,
an oscillator circuit including a plurality of ring oscillators, the oscillator circuit being configured to generate the oscillation signal in response to the selection signal.

12. A test method for a semiconductor device, the method comprising:
generating an oscillation signal based on a design rule pattern of a chip formed on a wafer;
counting the oscillation signal;
generating an N-bit signal based on the counting of the oscillation signal, N being a Natural number;
serializing the N-bit signal; and
outputting the serialized N-bit signal.

13. The method of claim 12, further including,
calculating an oscillation frequency of the oscillator based on the serialized signal,
comparing the calculated oscillation frequency with a reference frequency of the design rule pattern, and
determining whether the chip formed on the wafer is acceptable based on a result of the comparing.

14. The method of claim 12, wherein the generating of the oscillation signal includes,
generating a selection signal for selecting a ring oscillator from among at least one ring oscillator included in an oscillation unit based on an input signal, and
generating the oscillation signal using the selected ring oscillator.

15. The method of claim 14, wherein the generating of the selection signal includes,
sequentially latching the input signal received via an input terminal in response to a clock signal, and outputting at least one output signal, and
generating the selection signal based on the at least one output signal.

16. The method of claim 12, wherein the oscillation signal is buffered before being counted.

17. The method of claim 12, wherein the outputting of the serialized N-bit signal includes,
counting the oscillation signal, and
serializing and outputting the N-bit signal generated from based on the counting of the oscillation signal.

18. The method of claim 12, wherein the outputting of the serialized N-bit signal is performed by a shift register.

19. The method of claim 12, wherein the design rule pattern is one of a contact, an active resistor, a metal line, and a poly resistor.
